(19) United States
(12) Patent Application Publication
(10) Pub. No.: US 2026/0123433 A1
(43) Pub. Date: Apr. 30, 2026

(54) SEMICONDUCTOR STRUCTURE AND METHOD FOR MANUFACTURING THE SAME

(71) Applicant: United Microelectronics Corp., Hsinchu (TW)

(72) Inventors: Chung-Sung CHIANG, Kaohsiung City (TW); Chun-Hsien Lin, Tainan City (TW); I-Ming Tseng, Kaohsiung City (TW); Yu-Chun Chen, Kaohsiung City (TW); Yi-An Shih, Changhua County (TW)

(21) Appl. No.: 18/964,716

(22) Filed: Dec. 2, 2024

(30) Foreign Application Priority Data
Oct. 28, 2024 (TW) 113141094

(51) Int. Cl. H01L 23/00

(52) U.S. Cl. CPC H10W 42/121; H10D 1/716

(57) ABSTRACT

A semiconductor structure includes a substrate, a conductive pillar, a capacitor structure and dummy pillar structures. The conductive pillar is disposed in the substrate. The capacitor structure is disposed in the substrate, and is separated from the conductive pillar. The dummy pillar structures are randomly distributed between the conductive pillar and the capacitor structure.

This application claims the benefit of Taiwan application Serial No. 113141094, filed Oct. 28, 2024, the subject matter of which is incorporated herein by reference.

### BACKGROUND OF THE INVENTION

### Field of the Invention

The invention relates in general to a semiconductor structure and a method for manufacturing the same, and more particularly to a semiconductor structure including a conductive pillar and a method for manufacturing the same.

### Description of the Related Art

As the demand for the complexity of semiconductor devices continues to increase, the semiconductor industry currently uses through silicon via structures and transfer substrates (such as interposers) to electrically connect stacked wafers to shorten the distance between wafers, reduce component size, and increase the operating speed and operating bandwidth of semiconductor devices.

However, in the silicon through via structure and the transfer substrate, the coefficient of thermal expansion (CTE) between different materials (for example, between copper and silicon) may be too large, and when the thermal treatment step is performed during the process, cracks occur in the transfer substrate, and the metal may further extend along with the cracks, resulting in short circuits and a decrease in yield.

### SUMMARY OF THE INVENTION

The invention is directed to improving the stress relief of semiconductor structures, especially improving the occurrence of cracks in semiconductor structures, so that the formed semiconductor structures can have good electrical characteristics.

According to some embodiments, the present invention provides a semiconductor structure. The semiconductor structure includes a substrate, a conductive pillar, a capacitor structure and dummy pillar structures. The conductive pillar is disposed in the substrate. The capacitor structure is disposed in the substrate, and is separated from the conductive pillar. The dummy pillar structures are randomly distributed between the conductive pillar and the capacitor structure.

According to some embodiments, the present invention provides a method for manufacturing a semiconductor structure. The method includes the following steps: providing a substrate; forming a conductive pillar disposed in the substrate; and forming a capacitor structure and a plurality of dummy pillar structures in the substrate; wherein the dummy pillar structures are randomly distributed between the conductive pillar and the capacitor structure.

Since the dummy pillar structures are randomly distributed between the conductive pillar and the capacitor structure, the stress in the substrate can be well released.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1A shows a top view of a semiconductor structure according to an embodiment of the present invention.

FIG. 1B shows a cross-sectional view taken along line 1B-1B′ in FIG. 1A.

FIG. 2 illustrates a fabrication flow chart of the semiconductor structure of FIG. 1A.

FIG. 3 shows a schematic diagram of the semiconductor structure in FIG. 1A when cracks occur.

### DETAILED DESCRIPTION OF THE INVENTION

Various embodiments will be described in more detail below with reference to the accompanying drawings. The narrative content and diagrams are provided for illustration only and are not intended to be limiting. For clarity, some elements and/or symbols may be omitted in some drawings. In addition, elements in the drawings may not be drawn to real scale. It is contemplated that elements and features in one embodiment can be advantageously incorporated into another embodiment without further description.

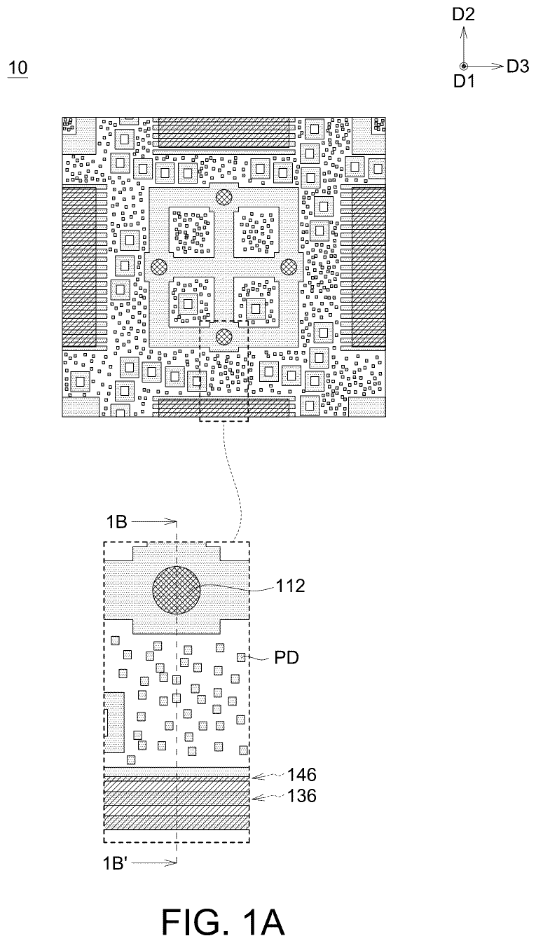

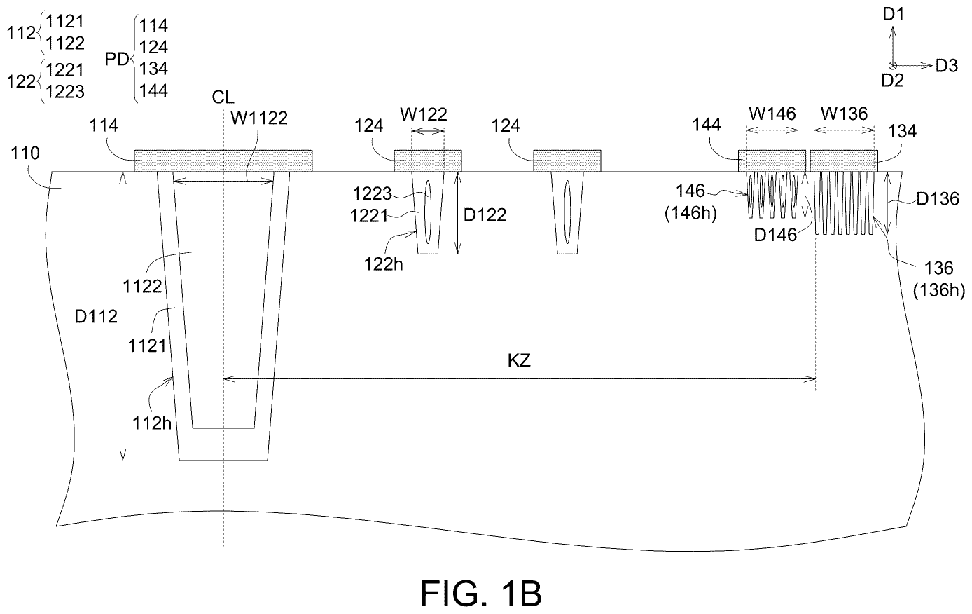

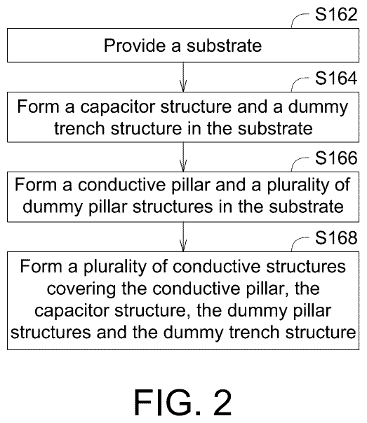

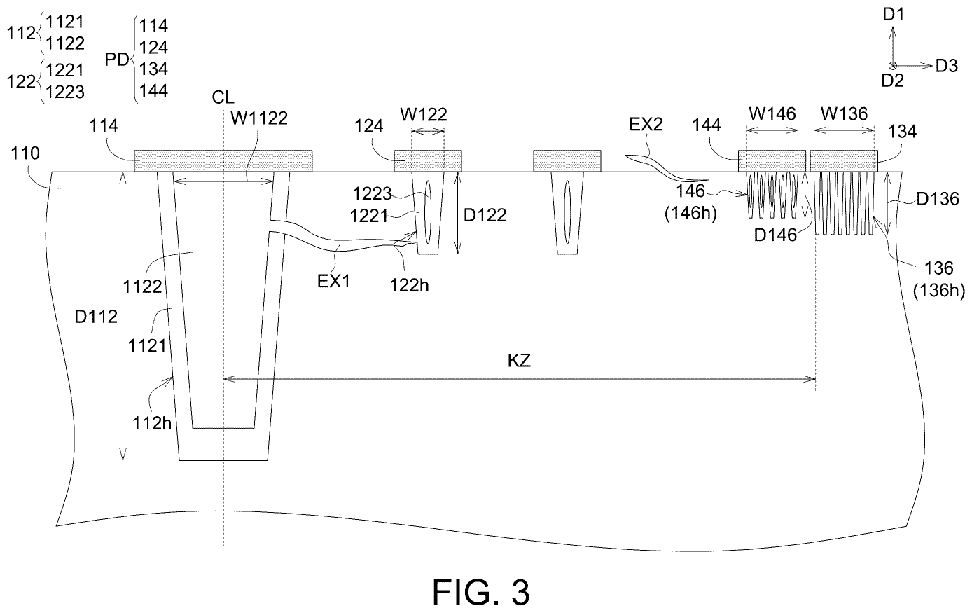

FIG. 1A shows a top view of a semiconductor structure 10 according to an embodiment of the present invention. FIG. 1B shows a cross-sectional view taken along line 1B-1B′ in FIG. 1A. FIG. 2 illustrates a fabrication flow chart of the semiconductor structure 10 of FIG. 1A. FIG. 3 shows a schematic diagram of the semiconductor structure 10 in FIG. 1A when cracks occur.

Referring to FIGS. 1A and 1B, the semiconductor structure 10 comprises a substrate 110, a conductive pillar 112, a plurality of dummy pillar structures 122 and a capacitor structure 136. In the present embodiment, the number of conductive pillar 112 and capacitor structure 136 is plural, but the invention is not limited thereto. The conductive pillars 112, the dummy pillar structures 122 and the capacitor structures 136 are all disposed in the substrate 110. The capacitor structures 136 and the conductive pillars 112 are separated from each other, and the dummy pillar structures 122 are randomly distributed between the conductive pillars 112 and the capacitor structures 136. The dummy pillar structures 122 are not concentrated in the area adjacent to the conductive pillars 112, but are distributed in the entire area between the conductive pillars 112 and the capacitor structures 136. In other words, the dummy pillar structures 122 can be provided in any area from an area adjacent to the conductive pillar 112 to an area far away from the conductive pillar 112 (for example, an area adjacent to the capacitor structure 136).

Compared with the comparative example in which the dummy pillar structures are only provided in an area adjacent to the conductive pillar (for example, surrounding the conductive pillar), since the dummy pillar structures 122 of the present invention are randomly distributed between the conductive pillar 112 and the capacitor structure 136, which has a better buffering effect on the stress borne by the substrate 110. Therefore, when the stress is generated between the substrate 110 and the conductive pillar 112 due to an excessive difference in the coefficient of thermal expansion (CTE) of the materials during the fabrication of the semiconductor structure 10 (for example, a thermal treatment), the stress of the present invention can be released more uniformly, which can better avoid the occurrence of cracks, and if cracks occur, it can also prevent the cracks from continuing to extend. As shown in FIG. 3, when a crack occurs, the conductive material (for example, copper) can form a protruding portion EX1 from the conductive pillar 112 along the crack. Due to the arrangement of the dummy pillar structures 122, the crack (or protruding portion EX1) can be prevented from extending further.

According to an embodiment, the substrate 110 may be an interposer, and the material of the substrate 110 may include silicon. The conductive pillar 112 includes a central portion 1122 and a first liner 1121 surrounding the central portion 1122 (as shown in FIG. 1B). The dummy pillar structure 122 includes an air gap 1223 and a second liner 1221 surrounding the air gap 1223. The material of the central portion 1122 includes a conductive material, such as a metal or other suitable conductive material. The materials of the first liner 1121 and the second liner 1221 include dielectric materials. The dielectric material is, for example, an oxide or other suitable dielectric material. Since the first liner 1121 and the second liner 1221 can be formed simultaneously through the same process, the materials of the first liner 1121 and the second liner 1221 can be the same as each other.

Referring to FIGS. 1A to 1B, an extension direction of a longitudinal axis of the conductive pillar 112 is, for example, parallel to the first direction D1. The top view of FIG. 1A is, for example, parallel to a plane formed by the second direction D2 and the third direction D3. The first direction D1, the second direction D2 and the third direction D3 may cross each other, for example, be perpendicular to each other, but the invention is not limited thereto.

As shown in FIG. 1B, the conductive pillar 112 has a central axis CL, the central axis CL passes through the geometric center of the conductive pillar 112, and the extension direction of the central axis CL is parallel to the extension direction of the longitudinal axis of the conductive pillar 112 (for example, parallel to the first direction D1). In an area KZ formed between the central axis CL and an edge of the capacitor structure 136 adjacent to the conductive pillar 112, the number of dummy pillar structures 122 disposed along the second direction D2 is greater than 1. In the embodiment of FIG. 1B, only two dummy pillar structures 122 are shown. However, the present invention is not limited thereto. The number of dummy pillar structures 122 disposed along the second direction D2 in the area KZ may be 3 or greater than 3.

According to an embodiment of the present invention, the semiconductor structure 10 further includes a dummy trench structure 146. The dummy trench structure 146 is disposed between the dummy pillar structures 122 and the capacitor structure 136. The capacitor structure 136 is, for example, a deep trench capacitor structure (DTC), and the material of the capacitor structure 136 includes, for example, polycrystalline silicon and dielectric materials (not limited thereto). The material of the dummy trench structure 146 includes, for example, a dielectric material. The dielectric material is, for example, an oxide.

Compared with the comparative example without a dummy trench structure, since the dummy trench structure 146 of the present invention is disposed between the dummy pillar structure 122 and the capacitor structure 136, the buffering effect to the stress on the substrate 110 is better. Therefore, during the fabrication of the semiconductor structure 10 (for example, a thermal treatment), when stress is generated between the substrate 110 and the conductive pillar 112 due to an excessive difference in the coefficient of thermal expansion (CTE) of the materials, the stress of the present invention can be released more uniformly, which can better avoid the occurrence of cracks, and if cracks occur, it can also prevent the cracks from continuing to extend. As shown in FIG. 3, when a crack occurs, the conductive material (for example, copper) can form a protruding portion EX2 along the crack. Due to the arrangement of the dummy trench structure 146, the crack (or protruding portion EX2) can be prevented from extending further.

According to an embodiment of the present invention, the semiconductor structure 10 further includes a plurality of conductive structures PD. The conductive structures PD cover the conductive pillars 112, the capacitor structures 136, the dummy pillar structures 122 and the dummy trench structures 146. For example, the conductive structures PD include a first conductive part 114, second conductive parts 124, a third conductive part 134 and a fourth conductive part 144. The first conductive part 114 covers the conductive pillar 112. The second conductive parts 124 cover the dummy pillar structures 112. The third conductive part 134 covers the capacitor structure 136. The fourth conductive part 144 covers the dummy trench structure 146. The materials of the first conductive part 114, the second conductive parts 124, the third conductive part 134 and the fourth conductive part 144 may include metal or other suitable conductive materials.

As shown in FIG. 1B, the first conductive part 114 is connected to (for example, in contact with) the conductive pillar 112, the second conductive parts 124 are connected to (for example, in contact with) the dummy pillar structures 122, and the third conductive part 134 is connected to (for example, in contact with) the capacitor structure 136, and the fourth conductive part 144 is connected to (for example, in contact with) the dummy trench structure 146.

As shown in FIG. 1B, the first conductive part 114 and the conductive pillar 112 overlap each other in the first direction D1, the second conductive parts 124 and the dummy pillar structures 122 overlap each other in the first direction D1, the third conductive part 134 and the capacitor structure 136 overlap each other in the first direction D1, and the fourth conductive part 144 and the dummy trench structure 146 overlap each other in the first direction D1. For example, the conductive pillar 112, the dummy pillar structures 122, the capacitor structure 136 and the dummy trench structure 146 overlap each other in the second direction D2 (the invention is not limited thereto).

According to an embodiment, a method of manufacturing the semiconductor structure 10 may include a planarization process (such as a chemical mechanical polishing process, CMP). During the planarization process, if the second conductive parts 124 are not disposed between the first conductive part 114 corresponding to the conductive pillar 112 and the third conductive part 134 corresponding to the capacitor structure 136, it may cause dishing in the area between the first conductive part 114 and the third conductive part 134. Moreover, compared with the comparative example in which the second conductive part and the dummy pillar structure are separately provided without being connected to each other, since the second conductive part 124 and the dummy pillar structure 122 are connected to each other according to one embodiment of the present invention, more supporting force can be provided, so it is more effective in preventing the formation of concavities, and also has a better effect on releasing the stress of the substrate 110.

According to an embodiment, a depth D112 of the conductive pillar 112 in the first direction D1 is greater than a depth D122 of the dummy pillar structure 122 in the first direction D1; a depth D136 of the capacitor structure 136 in the first direction D1 is greater than a depth D146 of the dummy trench structure 146 in the first direction D1; a depth D112 of the conductive pillar 112 in the first direction D1 is greater than the depth D136 of the capacitor structure 136 in the first direction D1. The depth D112 of the conductive pillar 112 is, for example, between 0.1 μm and 212 μm (e.g., 106 μm). The depth D122 of the dummy pillar structure 122 is, for example, between 0.1 μm and 12 μm (e.g., 6 μm). The depth D136 of the capacitor structure 136 is, for example, between 0.1 μm and 12 μm (e.g., 6 μm), and the depth D146 of the dummy trench structure 146 is, for example, between 0.1 μm and 6 μm (e.g., 3 μm), but the invention is not limited thereto.

According to an embodiment, a width W1122 of the central portion 1122 of the conductive pillar 112 in the second direction D2 is greater than a width W122 of the dummy pillar structure 122 in the second direction D2; a width W136 of the capacitor structure 136 in the second direction D2 is greater than a width W146 of the dummy trench structure 146 in the second direction D2; the width W1122 of the central portion 1122 of the conductive pillar 112 in the second direction D2 is greater than the width W136 of the capacitor structure 136 in the second direction D2. The width W1122 of the central portion 1122 of the conductive pillar 112 is, for example, between 0.1 μm and 22 μm (e.g., 11 μm). The width W122 of the dummy pillar structure 122 is, for example, between 0.1 μm and 2 μm (e.g., 1 μm). The width W136 of the capacitor structure 136 is, for example, between 0.1 μm and 1 μm (e.g., 0.5 μm), and the width W146 of the dummy trench structure 146 is, for example, between 0.1 μm and 0.5 μm (e.g., 0.25 μm). However, the invention is not limited thereto.

According to an embodiment, the conductive pillar 112 and the first conductive part 114 connected to the conductive pillar 112 can be electrically connected to other components, and the capacitor structure 136 and the third conductive part 134 connected to the capacitor structure 136 can also be electrically connected to other components to perform required functions. The dummy pillar structures 122, the second conductive part 124, the dummy trench structure 146 and the fourth conductive part 144 are not electrically connected to other components and are dummy structures.

In the present embodiment, the method for manufacturing the semiconductor structure 10 includes the following steps in sequence, but the invention is not limited thereto. The method of manufacturing the semiconductor structure 10 may include other steps, and the order of the steps may be adjusted according to requirements.

Referring to FIGS. 1B and 2, the method for manufacturing the semiconductor structure 10 includes steps S162 to S168. As shown in step S162, a substrate 110 is provided. The substrate 110 is, for example, a silicon interposer. Next, as shown in step S164, capacitor structures 136 and dummy trench structures 146 are formed in the substrate 110. The step S164 may include the following steps: forming a plurality of first trenches 136h corresponding to predetermined positions of the capacitor structures 136 in the substrate 110 and forming a plurality of second trenches 146h corresponding to predetermined positions of the dummy trench structures 146 in the substrate 110; filling the first trenches 136h and the second trenches 146h with dielectric material; filling the first trenches 136h with polycrystalline silicon material; performing a planarization process (such as chemical mechanical polishing process, CMP) to form capacitor structures 136 and dummy trench structures 146.

After step S164, step S166 is performed to form conductive pillars 112 and dummy pillar structures 122 in the substrate 110. Step S166 may include the following steps: forming first openings 112h and second openings 122h in the substrate 110; forming a dielectric material layers in the first openings 112h and the second openings 122h; forming a first conductive material layer on the dielectric material layer; removing the dielectric material layer and the first conductive material layer outside the first openings 112h and the second openings 122h through a planarization process, so that the dielectric material layer and the first conductive material layer disposed inside the first openings 112h form the conductive pillars 112, and the dielectric material layer disposed inside the second openings 122h form the dummy pillar structures 122. The dummy pillar structures 122 are randomly distributed between the conductive pillars 112 and the capacitor structures 136 (and the dummy trench structures 146).

After step S166, Step S168 is performed to form a plurality of conductive structures PD covering the conductive pillars 112, the capacitor structures 136, the dummy pillar structures 122 and the dummy trench structures 146. Step S168 may include the following steps: forming a second conductive material layer on the conductive pillars 112, the dummy pillar structures 122, the capacitor structures 136 and the dummy trench structures 146; patterning the second conductive material layer to retain the second conductive material layer corresponding to the conductive pillars 112, the capacitor structures 136, the dummy pillar structures 122 and the dummy trench structures 146; and performing planarization process to form the conductive structures PD.

According to the above, the present invention provides a semiconductor structure and a method for manufacturing the same. The semiconductor structure includes a substrate, a conductive pillar, a capacitor structure and dummy pillar structures. The conductive pillar is disposed in the substrate. The capacitor structure is disposed in the substrate and is separated from the conductive pillars. The dummy pillar structures are randomly distributed between the conductive pillar and the capacitor structure. Compared with the comparative example in which the dummy pillar structures are only provided in the area adjacent to the conductive pillar, since the dummy pillar structures of the present invention is randomly distributed between the conductive pillar and the capacitor structure, it has a better buffering effect on the stress borne by the substrate. The semiconductor structure may further include a dummy trench structure, and the dummy trench structure is disposed between the dummy pillar structures and the capacitor structure. Compared with the comparative example without the dummy trench structure, since the dummy trench structure of the present invention is disposed between the dummy pillar structures and the capacitor structure, it has a better buffering effect on the stress borne by the substrate. Therefore, through the design of the dummy pillar structures and the dummy trench structure of the present invention, the semiconductor structure has good ability to release stress. During manufacturing the semiconductor structures (for example, a thermal treatment), when stress is generated between the substrate and the conductive pillars due to an excessive difference in the coefficient of thermal expansion (CTE) of the materials, on the one hand, the stress can be released more evenly to avoid the occurrence of cracks, and on the other hand, the dummy pillar structures and the dummy trench structure can appropriately prevent cracks from continuing to extend when cracks occur. Thereby, the semiconductor structure of the present invention can avoid the occurrence of short circuit and has excellent yield.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor structure, comprising:
a substrate;
a conductive pillar disposed in the substrate;
a capacitor structure disposed in the substrate and separated from the conductive pillar; and
a plurality of dummy pillar structures randomly distributed between the conductive pillar and the capacitor structure.

2. The semiconductor structure according to claim 1, further comprising a plurality of conductive structures, wherein the conductive structures cover the conductive pillar, the capacitor structure and the dummy pillar structures.

3. The semiconductor structure according to claim 1, further comprising a plurality of conductive structures, wherein the conductive structures comprises a first conductive part and a plurality of second conductive parts, the first conductive part covers the conductive pillar, and the second conductive parts cover the dummy pillar structures.

4. The semiconductor structure according to claim 3, wherein the second conductive parts are connected to the dummy pillar structures.

5. The semiconductor structure according to claim 3, wherein an extension direction of a longitudinal axis of the conductive pillar is parallel to a first direction, and the second conductive parts and the dummy pillar structures overlap each other in the first direction.

6. The semiconductor structure according to claim 5, wherein a depth of the conductive pillar in the first direction is greater than a depth of the dummy pillar structures in the first direction.

7. The semiconductor structure according to claim 1, wherein the conductive pillar comprises a central portion and a first liner surrounding the central portion, each of the dummy pillar structures comprises an air gap and a second liner surrounding the air gap, the central portion comprises a conductive material, and the first liner and the second liner comprise a dielectric material.

8. The semiconductor structure according to claim 1, further comprising a dummy trench structure disposed between the dummy pillar structures and the capacitor structure.

9. The semiconductor structure according to claim 8, wherein a depth of the capacitor structure in a first direction is greater than a depth of the dummy trench structure in the first direction, and the first direction is parallel to an extension direction of a longitudinal axis of the conductive pillar.

10. The semiconductor structure according to claim 8, wherein a material of the dummy trench structure comprises a dielectric material.

11. A method for manufacturing a semiconductor structure, comprising:
providing a substrate;
forming a conductive pillar disposed in the substrate; and
forming a capacitor structure and a plurality of dummy pillar structures in the substrate;
wherein the dummy pillar structures are randomly distributed between the conductive pillar and the capacitor structure.

12. The method according to claim 11, wherein the method for forming the conductive pillar and the dummy pillar structures further comprising:
forming a first opening and a plurality of second openings;
forming a dielectric material layer in the first opening and the second openings;
forming a first conductive material layer on the dielectric material layer; and
removing the dielectric material layer and the first conductive material layer outside the first opening and the second openings by a first planarization process, so that the dielectric material layer and the first conductive material layer disposed inside the first opening forming the conductive pillar, and the dielectric material layer disposed inside the second openings forming the dummy pillar structures.

13. The method according to claim 12, further comprising:
forming a second conductive material layer on the conductive pillar and the dummy pillar structures;
patterning the second conductive material layer to retain the second conductive material layer corresponding to the conductive pillar, the capacitor structure and the dummy pillar structures; and
performing a second planarization process, so that the second conductive material layer covering to the conductive pillar, the capacitor structure and the dummy pillar structures form a plurality of conductive structures.

14. The method according to claim 13, wherein the conductive structures comprises a first conductive part and a plurality of second conductive parts, the first conductive part covers the conductive pillar, the second conductive parts cover the dummy pillar structures, and the second conductive parts are connected to the dummy pillar structures.

15. The method according to claim 13, wherein an extension direction of a longitudinal axis of the conductive pillar is parallel to a first direction, and the second conductive parts and the dummy pillar structures overlap each other in the first direction.

16. The method according to claim 15, wherein a depth of the conductive pillar in the first direction is greater than a depth of the dummy pillar structures in the first direction.

17. The method according to claim 11, wherein the conductive pillar comprises a central portion and a first liner surrounding the central portion, each of the dummy pillar structures comprises an air gap and a second liner surrounding the air gap, the central portion comprises a conductive material, and the first liner and the second liner comprise a dielectric material.

18. The method according to claim 11, further comprising forming a dummy trench structure disposed between the dummy pillar structures and the capacitor structure.

19. The method according to claim 18, wherein a depth of the capacitor structure in a first direction is greater than a depth of the dummy trench structure in the first direction, and the first direction is parallel to an extension direction of a longitudinal axis of the conductive pillar.

20. The method according to claim 18, wherein a material of the dummy trench structure comprises a dielectric material.
